(19) United States
(12) Patent Application Publication
(10) Pub. No.: US 2026/0285286 A1
(43) Pub. Date: Sep. 24, 2026

(54) METHODS FOR PERFORMING SEQUENTIAL INVARIANT EXTENDED KALMAN FILTERING IN NAVIGATION AND POSITIONING TASKS

(71) Applicant: HARBIN INSTITUTE OF TECHNOLOGY, Harbin (CN)

(72) Inventors: Feng SHEN, Harbin (CN); Wenqiang LI, Harbin (CN); Yue YUAN, Harbin (CN); Yi LIANG, Harbin (CN); Juan YIN, Harbin (CN)

(73) Assignee: HARBIN INSTITUTE OF TECHNOLOGY, Harbin (CN)

(21) Appl. No.: 19/565,569

(22) Filed: Mar. 13, 2026

(30) Foreign Application Priority Data
Mar. 18, 2025 (CN) 202510319117.4

(51) Int. Cl. B60W 10/20; G01S 19/39; G06F 17/16; G06F 30/20

(52) U.S. Cl. CPC B60W 10/20; G01S 19/393; G06F 17/16; G06F 30/20; B60W 2710/202; B60W 2710/207

(57) ABSTRACT

The present disclosure relates to a method for performing sequential invariant extended Kalman filtering in a navigation and positioning task. The method solves the problem that efficient fusion of observations in different frames is difficult to achieve under an IEKF framework, and geometric consistency of covariance propagation cannot be guaranteed. The method includes: dividing observations of navigation sensors according to different frames; constructing a state vector in a Lie group form; performing modeling an output of an inertial measurement unit; performing state propagation according to Lie group state equations; calculating propagation of a covariance matrix; establishing a left-invariant observation equation and a right-invariant observation equation according to the two types of observations; synchronously updating a state estimation through a left-invariant extended Kalman filter and a right-invariant extended Kalman filter; and mapping a left-invariant covariance matrix and a right-invariant covariance matrix via a common state covariance matrix to complete sequential fusion.

### CROSS-REFERENCE TO RELATED APPLICATIONS

This application claims priority to Chinese Application No. 202510319117.4 filed on Mar. 18, 2025, the entire contents of which are hereby incorporated by reference.

### TECHNICAL FIELD

The present disclosure relates to a computer field, and in particular, to a method for performing sequential invariant extended Kalman filtering in a navigation and positioning task.

### BACKGROUND

High-precision positioning of a vehicle is a fundamental basis of an autonomous driving system, and reliability thereof directly affects decision-making, planning, and driving safety. In complex urban environments, due to factors such as obstruction by high-rise buildings, multipath effects, and signal interference, positioning accuracy of a Global Navigation Satellite System (GNSS) is significantly degraded (with an error typically exceeding 4 meters), which makes it difficult to satisfy centimeter-level positioning requirements of autonomous driving. Although an Inertial Measurement Unit (IMU) can provide short-term continuous pose estimation through dead reckoning, errors thereof accumulate over time. In particular, in dynamic scenarios, rapid changes in a vehicle pose and a motion state further aggravate positioning drift.

To overcome limitations of a single sensor, multi-sensor fusion technology has become a research focus. A Kalman Filter (KF) and extended forms thereof, such as an Extended Kalman Filter (EKF), have been widely applied in GNSS/IMU integrated positioning. By fusing global position constraints provided by GNSS with high-frequency motion measurements of an IMU, positioning robustness can be improved. However, in nonlinear systems (such as rotational operations in vehicle attitude estimation), conventional EKF introduces errors due to linearization approximation. In addition, during dynamic coordinate transformations (e.g., mapping between a body coordinate system and a navigation coordinate system), distortion of state estimation may occur. To address this issue, an Invariant Extended Kalman Filter (IEKF) has been proposed. By utilizing Lie group structural properties of a state space and maintaining geometric invariance of error dynamics, the IEKF significantly reduces linearization errors and has demonstrated superior performance in fields such as inertial navigation and Simultaneous Localization and Mapping (SLAM).

However, existing IEKF methods still suffer from key bottlenecks when fusing observation data from multiple coordinate systems. First, an observation model of an IEKF is typically configured to adapt to only a single frame (e.g., a navigation frame or a body frame), which prevents observations from different frames from being directly fused. For example, GNSS provides position observations in the navigation frame, whereas devices such as a wheel speed sensor and zero-velocity detection provide velocity or attitude constraints in the body frame, making it difficult for a conventional IEKF to utilize both types of information in a synchronized manner. Second, a Left-Invariant IEKF (L-IEKF) and a Right-Invariant IEKF (R-IEKF) are respectively designed for observations in different frames, and error propagation mechanisms and covariance update mechanisms thereof are mutually incompatible. If directly used in combination, a state covariance matrix may fail to correctly reflect an actual error distribution, thereby reducing filtering stability.

Therefore, how to achieve efficient fusion of observations from multiple frames under an IEKF framework while ensuring geometric consistency of covariance propagation has become a key challenge for improving vehicle positioning accuracy in complex scenarios.

In view of the above, the present disclosure aims to propose a method for performing sequential invariant extended Kalman filtering in a navigation and positioning task to solve the problem that efficient fusion of multi-frame observations is difficult to achieve within an IEKF framework and geometric consistency of covariance propagation cannot be guaranteed.

### SUMMARY

To achieve the above objectives, one or more embodiments of the present disclosure adopt the following technical solution: a method for performing sequential invariant extended Kalman filtering in a navigation and positioning task is provided, the method includes the following steps:
Step S1: dividing observations of navigation sensors into two types according to a frame in which the navigation sensors are located, wherein one type is observations in a body frame of a vehicle, and the other type is observations in a navigation frame.
Step S2: constructing a state vector in a Lie group form.
Step S3: performing modeling on an output of an inertial measurement unit (IMU).
Step S4: performing state propagation according to Lie group state equations;
Step S5: calculating propagation of a covariance matrix.
Step S6: establishing a left-invariant observation equation and a right-invariant observation equation according to the two types of observations divided in step S1.
Step S7: synchronously updating a state estimation through a left-invariant extended Kalman filter and a right-invariant extended Kalman filter, and mapping a left-invariant covariance matrix and a right-invariant covariance matrix via a common state covariance matrix to complete sequential fusion.

In some embodiments, the observations in the body frame in step S1 include a Non-Holonomic Constraint (NHC), and the observations in the navigation frame in step S1 include a position provided by a Global Navigation Satellite System (GNSS).

In some embodiments, the state vector in the Lie group form in step S2 is:

$${\hat{χ}}_{k} = ( \begin{matrix}{\hat{R}}_{k} \\ {\hat{x}}_{k} \\ {\hat{x}}_{k}\end{matrix} ) = ( {\hat{R}}_{k} , {\hat{x}}_{k} , {\hat{x}}_{k} ) ,$$

where

$${\hat{R}}_{k} = ( {\hat{R}}_{k}^{N} , {\hat{R}}_{k}^{C} ) , {\hat{x}}_{k} = ( {\hat{v}}_{k}^{N} , {\hat{p}}_{k}^{N} ) , {\hat{x}}_{k} = ( {\hat{b}}_{k}^{ω} , {\hat{b}}_{k}^{a} , {\hat{p}}_{k}^{C} ) ,$$

$${\hat{R}}_{k}^{N}$$

denotes an attitude ultimate of the vehicle in the navigation frame at a time k,

$${\hat{v}}_{k}^{N}$$

denotes a velocity estimate of the vehicle in the navigation frame at the time k,

$${\hat{p}}_{k}^{N}$$

denotes a position estimate of the vehicle in the navigation frame at the time k,

$${\hat{b}}_{k}^{ω}$$

denotes an estimated value of gyroscope bias of the IMU at the time k,

$${\hat{b}}_{k}^{a}$$

denotes an estimated value of accelerometer bias at the time k,

$${\hat{R}}_{k}^{C}$$

denotes an estimated value of a rotation of a lever arm of the IMU relative to a vehicle center at the time k, and

$${\hat{p}}_{k}^{C}$$

denotes an estimated value of a displacement of the lever arm of the IMU relative to the vehicle center at the time k.

In some embodiments, the performing modeling on an output of an inertial measurement unit (IMU) in step S3 includes:

$${ω}_{k}^{imu} = {ω}_{k} + {b}_{k}^{( o} + {w}_{k}^{ω} ,$$

$${a}_{k}^{imu} = {a}_{k} + {b}_{k}^{a} + {w}_{k}^{a} ,$$

where ωₖ denotes a true value of an angular velocity of the IMU at the time k, aₖ denotes a true value of an acceleration of the IMU at the time k,

$${ω}_{k}^{imu} and {a}_{k}^{imu}$$

denote output values of the angular velocity and the acceleration of the IMU at the time k,

$${b}_{k}^{ω}$$

denotes an angular velocity bias at the time k,

$${b}_{k}^{a}$$

denotes an acceleration bias at the time k,

$${w}_{k}^{ω}$$

denotes a random error of the angular velocity at the time k, and

$${w}_{k}^{a}$$

denotes a random error of the acceleration at the time k.

In some embodiments, the performing state propagation according to Lie group state equations in step S4 includes:

$${\hat{R}}_{k + 1 \vert k}^{N} = {\hat{R}}_{k \vert k}^{N} exp ( {( {ω}_{k} d t )}_{\times } )$$

$${\hat{v}}_{k + 1 \vert k}^{N} = {\hat{v}}_{k \vert k}^{N} + ( {\hat{R}}_{k \vert k}^{N} {a}_{k} + g ) dt$$

$${\hat{p}}_{k + 1 \vert k}^{N} = {\hat{p}}_{k \vert k}^{N} + {\hat{v}}_{k \vert k}^{N} dt$$

$${\hat{b}}_{k + 1 \vert k}^{ω} = {\hat{b}}_{k \vert k}^{ω} + {w}_{k}^{{b}_{ω}}$$

$${\hat{b}}_{k + 1 \vert k}^{a} = {\hat{b}}_{k \vert k}^{a} + {w}_{k}^{{b}_{a}}$$

$${\hat{R}}_{k + 1 \vert k}^{C} = {\hat{R}}_{k \vert k}^{C} exp ( {( {w}_{k}^{{R}^{C}} dt )}_{\times } )$$

$${\hat{p}}_{k + 1 \vert k}^{C} = {\hat{p}}_{k \vert k}^{C} + {w}_{k}^{{p}^{C}} ,$$

where a subscript k+1|k denotes estimating data at a time k+1 by using data at the time k, g denotes a gravitational acceleration,

$${w}_{k}^{{b}_{ω}}$$

denotes a random error of angular velocity bias at the time k,

$${w}_{k}^{{b}_{a}}$$

denotes a random error of acceleration bias at the time k,

$${w}_{k}^{{R}^{C}}$$

denotes a random error of the rotation of the lever arm at the time k, and

$${w}_{k}^{{p}^{C}}$$

denotes a random error of the displacement of the lever arm at the time k.

In some embodiments, the calculating propagation of a covariance matrix in the step S5 includes:

$${P}_{k + 1 \vert k} = {F}_{k} {P}_{k \vert k} {F}_{k}^{T} + {G}_{k} {Q}_{k} {G}_{k}^{T} ,$$

where Fₖ denotes a Jacobian matrix of the state equation with respect to a Lie-algebra error at the time k, Gₖ denotes a noise driving matrix at the time k, P_{k|k} denotes a covariance matrix of the Lie-algebra error at the time k, and Qₖ denotes a noise covariance matrix at the time k.

In some embodiments, the establishing a left-invariant observation equation and a right-invariant observation equation in step S6 includes:

$${y}_{k + 1}^{L} = {p}_{k + 1 \vert k}^{N} + {n}_{k}^{GNSS} ,$$

$${v}_{k + 1}^{C} = [ \begin{matrix}{v}_{k + 1}^{for} \\ {v}_{k + 1}^{lat} \\ {v}^{up}\end{matrix} ] = {( {\hat{R}}_{k + 1 \vert k}^{C} )}^{T} ( {( {\hat{R}}_{k + 1 \vert k}^{N} )}^{T} {\hat{v}}_{k + 1 \vert k}^{N} + {( {ω}_{k} )}_{\times } {\hat{p}}_{k + 1 \vert k}^{C} ) ,$$

$${y}_{k + 1}^{R} = [ \begin{matrix}{v}_{k , u}^{lat} \\ {v}_{k}^{up}\end{matrix} ] + {n}_{k}^{v} ,$$

where

$${n}_{k}^{GNSS}$$

denotes a GNSS observation noise at the time k,

$${n}_{k}^{v}$$

denotes an NHC observation noise at the time k,

$${v}_{k + 1}^{C} = [ \begin{matrix}{v}_{k + 1}^{for} \\ {v}_{k + 1}^{lat} \\ {v}_{k + 1}^{up}\end{matrix} ]$$

denotes velocities of the vehicle at the time k+1,

$${v}_{k + 1}^{for}$$

denotes a forward velocity at the time k+1,

$${v}_{k + 1}^{lat}$$

denotes a lateral velocity at the time k+1,

$${v}_{k}^{up}$$

denotes a vertical velocity at the time k,

$${\hat{R}}_{k + 1 \vert k}^{C}$$

denotes a rotation matrix representing a relationship between the lever arm of the IMU and the vehicle center, and

$${\hat{p}}_{k + 1 \vert k}^{C}$$

denotes a displacement vector of the lever arm.

In some embodiments, the mapping a left-invariant covariance matrix and a right-invariant covariance matrix via a common state covariance matrix in step S7 includes:

$${P}_{k + 1 \vert k + 1}^{L} = {F}_{k + 1}^{L} {{P}_{State} ( {F}_{k + 1}^{L} )}^{T} ,$$

$${P}_{State} = {( {F}_{k + 1}^{L} )}^{- 1} {{P}_{k + 1 \vert k + 1}^{L} ( {( {F}_{k + 1}^{L} )}^{- 1} )}^{T} ,$$

$${P}_{k + 1 \vert k + 1}^{R} = {F}_{k + 1}^{R} {{P}_{State} ( {F}_{k + 1}^{R} )}^{T} ,$$

$${P}_{State} = {( {F}_{k + 1}^{R} )}^{- 1} {{P}_{k + 1 \vert k + 1}^{R} ( {( {F}_{k + 1}^{R} )}^{- 1} )}^{T} ,$$

where Pₛₜₐₜₑ denotes the common state covariance matrix,

$${P}_{k + 1 \vert k + 1}^{L}$$

denotes a covariance matrix of a left-invariant Lie-algebra error at the time k+1,

$${P}_{k + 1 \vert k + 1}^{R}$$

denotes a covariance matrix of a right-invariant Lie-algebra error at the time k+1,

$${F}_{k + 1}^{L}$$

denotes a Jacobian matrix of a left-invariant state equation with respect to the left-invariant Lie-algebra error at the time k+1, and

$${F}_{k + 1}^{R}$$

denotes a Jacobian matrix of a right-invariant state equation with respect to the right-invariant Lie-algebra error at the time k+1.

In some embodiments, the method further includes: extracting a high-precision position of a current vehicle based on a sequential fusion result of step S7; determining offset data based on the high-precision position and a LiDAR point cloud; in response to determining that the offset data is greater than an offset threshold, determining a steering wheel angle and a vehicle acceleration based on the offset data; driving a steering actuator motor to output a torque and a rotation angle based on the steering wheel angle; and determining a required torque command of a drive motor based on the vehicle acceleration, and controlling the drive motor to output a driving torque or a regenerative braking torque based on the required torque command.

In some embodiments, the offset threshold is related to a controllability, and the controllability is related to a current covariance matrix and a visibility.

In some embodiments, step S3 further includes: acquiring a mapping relationship b_{base}(T); and based on a core temperature Tₖ of the IMU at the time k and the mapping relationship b_{base}(T), determining the angular velocity bias

$${b}_{k}^{ω}$$

at the time k and the acceleration bias

$${b}_{k}^{a}$$

at the time k.

Based on the same inventive concepts, one or more embodiments of the present disclosure further provide a computer device, including: a memory and a processor. The memory stores computer instructions. When the processor runs the computer instructions stored in the memory, the processor executes the method for performing sequential invariant extended Kalman filtering in a navigation and positioning task mentioned above.

Based on the same inventive concept, one or more embodiments of the present disclosure further provide a non-transitory computer-readable storage medium storing computer instructions. The computer instructions, when executed by a processor, cause the processor to perform the method for performing sequential invariant extended Kalman filtering in a navigation and positioning task mentioned above.

### BRIEF DESCRIPTION OF THE DRAWINGS

The present disclosure is further described in terms of exemplary embodiments. These exemplary embodiments are described in detail with reference to the drawings. The drawings are not to scale. These embodiments are non-limiting schematic embodiments, in which like reference numerals represent similar structures throughout the several views of the drawings, and wherein:

FIG. 1 is a schematic diagram of a method for performing sequential invariant extended Kalman filtering in a navigation and positioning task according to some embodiments of the present disclosure;

FIG. 2 is a flowchart of an exemplary process for sequential invariant extended Kalman filtering in a navigation and positioning task according to some embodiments of the present disclosure; and

FIG. 3 is a flowchart of another exemplary process for sequential invariant extended Kalman filtering in a navigation and positioning task according to some embodiments of the present disclosure.

### DETAILED DESCRIPTION

The technical solutions in the embodiments of the present disclosure are clearly and completely described below with reference to the accompanying drawings in the embodiments of the present disclosure. It should be noted that the embodiments in the present disclosure and the features in the embodiments may be combined with each other without conflict. The described embodiments are merely a part of the embodiments of the present disclosure, rather than all of the embodiments.

In the equations of the present disclosure, the same letter denotes the same variable.

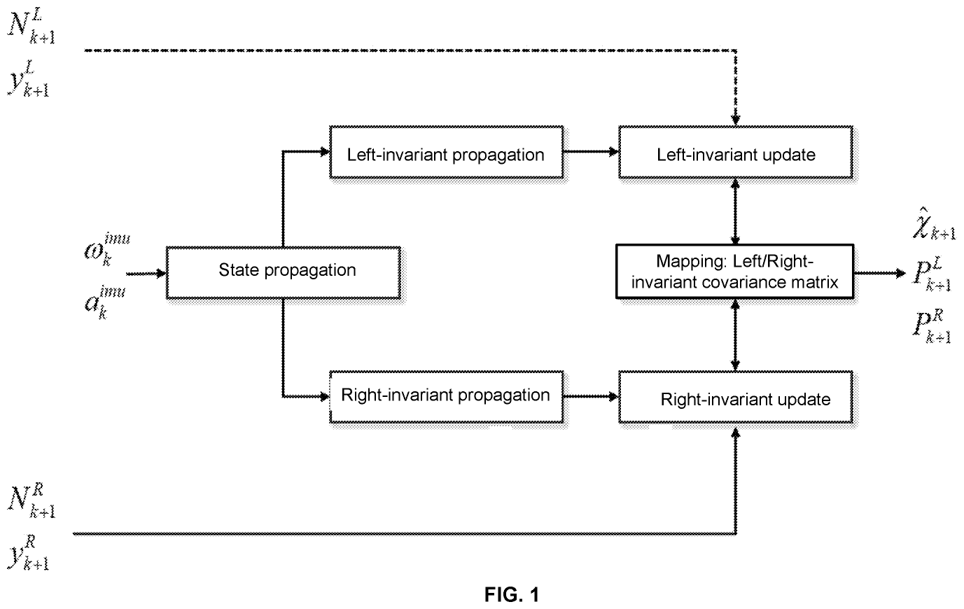

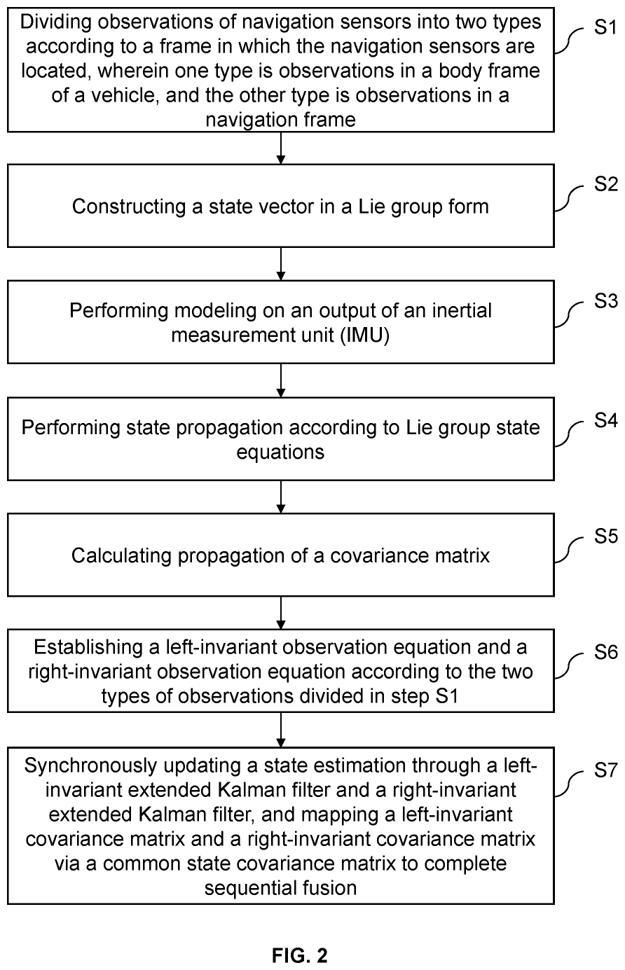

FIG. 1 is a schematic diagram of a method for performing sequential invariant extended Kalman filtering in a navigation and positioning task according to some embodiments of the present disclosure. FIG. 2 is a flowchart of an exemplary process for sequential invariant extended Kalman filtering in a navigation and positioning task according to some embodiments of the present disclosure.

With reference to FIG. 1 and FIG. 2, an embodiment of the present disclosure provides a method for performing sequential invariant extended Kalman filtering in a navigation and positioning task, including:
Step S1, dividing observations of navigation sensors into two types according to a frame in which the navigation sensors are located, wherein one type is observations in a body frame of a vehicle, and the other type is observations in a navigation frame.
Step S2, constructing a state vector in a Lie group form.
Step S3, performing modeling on an output of an inertial measurement unit (IMU).
Step S4, performing state propagation according to Lie group state equations.
Step S5, calculating propagation of a covariance matrix.
Step S6, establishing a left-invariant observation equation and a right-invariant observation equation according to the two types of observations divided in step S1.
Step S7, synchronously updating a state estimation through a left-invariant extended Kalman filter and a right-invariant extended Kalman filter, and mapping a left-invariant covariance matrix and a right-invariant covariance matrix via a common state covariance matrix to complete sequential fusion.

The method for performing sequential invariant extended Kalman filtering in a navigation and positioning task in the embodiments of the present disclosure may be applied to an autonomous driving system and executed by a control system.

The autonomous driving system refers to a system that enables a vehicle to drive autonomously without human intervention through artificial intelligence, sensors, or the like. In some embodiments, the autonomous driving system may include a sensing system (including various sensors), a control system, an interaction system (e.g., a user interface), etc.

The control system refers to a system that processes data, generates instructions, and controls the vehicle. For example, the control system may include a central processing unit (CPU), a graphics processing unit (GPU), an application-specific integrated circuit (ASIC), or any combination thereof. The data may come from different components in the autonomous driving system or other data sources. The instructions may be sent to the different components. The control system may also include other components related to the above content. For example, the control system may include a computer, a mobile phone, a server, an industrial control computer, a circuit board with computing functions, or the like.

In some embodiments of the present disclosure, through the above-proposed method, by dividing the sensor observations into two types of observations in the body frame and the navigation frame, observation data between multiple frames is effectively processed, so that observations in different frames can be fused more efficiently under an invariant extended Kalman filter (IEKF) framework, thereby improving fusion accuracy and efficiency of multi-source information.

In a traditional extended Kalman filter (EKF), a problem of geometric consistency exists in covariance propagation. By using the state vector in the Lie group form, a geometric relationship in a navigation system is described, geometric consistency in a covariance propagation process is ensured, and problems of error accumulation and inconsistency occurring in traditional methods are avoided. Regarding invariance properties, left-invariant and right-invariant observation equations are constructed to perform state estimation within an invariant framework. This approach enhances the stability of the filtering process, making it more robust to complex changes and measurement noise in navigation and positioning tasks within dynamic environments.

Furthermore, the above method implements sequential fusion by synchronously updating the state estimates of the left-invariant and right-invariant extended Kalman filters, and by mapping the covariances using a common state covariance matrix. This sequential fusion approach balances state estimation and covariance propagation among multiple filters, thereby improving the estimation accuracy and real-time performance of the entire autonomous driving system.

The method proposed in the embodiments of the present disclosure can effectively handle information fusion tasks from multiple different sources (e.g., the IMU, an external positioning sensor, etc.), especially in complex navigation environments involving conversion between multiple frames and the comprehensive utilization of multi-source data. The method exhibits strong adaptability and is capable of addressing navigation and positioning challenges in highly dynamic and complex environments.

In some embodiments, the observations in the body frame in step S1 include a Non-Holonomic Constraint (NHC), and the observations in the navigation frame include a position provided by a Global Navigation Satellite System (GNSS). For example, the observations in the body frame may include an acceleration sensed by the IMU, and a determination of whether the vehicle is slipping or sideslipping based on wheel information, etc. The observations in the navigation frame may include coordinate information of the vehicle provided by a Global Positioning System (GPS). By combining observations of a plurality of navigation sensors, positioning accuracy can be improved. The NHC means that a moving vehicle moves along a forward direction of the body frame without sideslip, i.e., a lateral velocity is zero; and the moving vehicle moves close to a ground surface without bumping, i.e., a vertical velocity is zero. The constraint is established in the body frame, with a condition that the lateral velocity and the vertical velocity of the vehicle are zero as constraint conditions, and a velocity obtained by mechanical arrangement is converted to the body frame as an observation value. Advantages of the constraint lies in utilizing only information of the vehicle itself to maintain a motion state.

In some embodiments, the state vector in the Lie group form in step S2 is Equation (1):

$${\hat{χ}}_{k} = ( \begin{matrix}{\hat{R}}_{k} \\ {\hat{x}}_{k} \\ {\hat{x}}_{k}\end{matrix} ) = ( {\hat{R}}_{k} , {\hat{x}}_{k} , {\hat{x}}_{k} ) . \qquad ( 1 )$$

In the Equation (1),

$${\hat{R}}_{k} = ( {\hat{R}}_{k}^{N} , {\hat{R}}_{k}^{C} ) , {\hat{x}}_{k} = ( {\hat{v}}_{k}^{N} , {\hat{p}}_{k}^{N} ) , {\hat{x}}_{k} = ( {\hat{b}}_{k}^{ω} , {\hat{b}}_{k}^{a} , {\hat{p}}_{k}^{C} ) ,$$

$${\hat{R}}_{k}^{N}$$

denotes an attitude estimate of the vehicle in the navigation frame at a time k,

$${\hat{v}}_{k}^{N}$$

denotes a velocity estimate of the vehicle in the navigation frame at the time k,

$${\hat{p}}_{k}^{N}$$

denotes a position estimate of the vehicle in the navigation frame at the time k,

$${\hat{b}}_{k}^{ω}$$

denotes an estimated value of gyroscope bias of the IMU at the time k,

$${\hat{b}}_{k}^{a}$$

denotes an estimated value of accelerometer bias at the time k,

$${\hat{R}}_{k}^{c}$$

denotes an estimated value of a rotation of a lever arm of the IMU relative to a vehicle center at the time k, and

$${\hat{p}}_{k}^{c}$$

denotes an estimated value of a displacement of the lever arm of the IMU relative to the vehicle center at the time k.

In some embodiments of the present disclosure, by introducing the estimation of the rotation and the displacement of the lever arm of the IMU relative to the vehicle center, an impact of a change in a position of the IMU on navigation and positioning is considered in a filtering process, and a problem that the change in the position and a direction of the IMU relative to the vehicle center significantly affects positioning accuracy is avoided. By accurately estimating the rotation/displacement of the lever arm of the IMU relative to the vehicle center, errors can be effectively reduced, and accuracy and reliability of navigation and positioning can be improved.

In some embodiments of the present disclosure, by describing attitude changes and position transformations through the state vector in the Lie group form, performance of the EKF in a highly nonlinear system is improved, and approximation errors caused by traditional linearization methods are avoided.

In some embodiments, modeling of the output of the IMU in step S3 is performed using Equation (2.1) and Equation (2.2):

$${ω}_{k}^{i m u} = {ω}_{k} + {b}_{k}^{ω} + {w}_{k}^{ω} , \qquad ( 2.1 )$$

$${a}_{k}^{i m u} = {a}_{k} + {b}_{k}^{a} + {w}_{k}^{a} . \qquad ( 2.2 )$$

In the Equation (2.1) and Equation (2.2) ωₖ denotes a true value of an angular velocity of the IMU at the time k, aₖ denotes a true value of an acceleration of the IMU at the time k,

$${ω}_{k}^{i m u} and {a}_{k}^{i m u}$$

denote output values of the angular velocity and the acceleration of the IMU at the time k,

$${b}_{k}^{ω}$$

is an angular velocity bias at the time k,

$${b}_{k}^{a}$$

is an acceleration bias at the time k,

$${w}_{k}^{ω}$$

is a random error of the angular velocity at the time k, and

$${w}_{k}^{a}$$

is a random error of the acceleration at the time k.

In some embodiments of the present disclosure, by considering bias errors of the IMU (e.g., the angular velocity bias and the acceleration bias) in a modeling process, an impact of these error sources on a filtering result can be effectively reduced. The biases often affect accuracy of an inertial sensor. Without compensation, the biases may cause long-term error accumulation. The embodiments of the present disclosure can significantly improve filtering accuracy by modeling and compensating for these biases. The method enables the filter to better adapt to uncertainty in actual measurements, thereby providing more accurate positioning and navigation results.

In some embodiments, step S3 further includes: acquiring a mapping relationship b_{base}(T); based on a core temperature Tx of the IMU at the time k and the mapping relationship b_{base}(T), determining the angular velocity bias

$${b}_{k}^{ω}$$

at the time k and the acceleration bias

$${b}_{k}^{a}$$

at the time K.

The mapping relationship b_{base}(T) refers to a mapping relationship between a bias value of the IMU and the core temperature of the IMU under an ideal static condition without external interference and time-varying drift.

In some embodiments, the mapping relationship b_{base}(T) may be a function determined in advance through a calibration experiment. For example, before leaving the factory or before use, the IMU is placed in a temperature-controlled chamber. Static outputs of the IMU are measured at different temperature points T. Bias values at each temperature are calculated to fit the function b_{base}(T).

In some embodiments, the control system may directly read the core temperature from the IMU to acquire the core temperature Tₖ at the time k.

In some embodiments, the control system may determine the angular velocity bias

$${b}_{k}^{ω}$$

at the time k and the acceleration bias

$${b}_{k}^{a}$$

at the time k in various ways based on the core temperature Tx of the IMU at the time k and the mapping relationship b_{base}(T). For example, the angular velocity bias

$${b}_{k}^{ω}$$

and the acceleration bias

$${b}_{k}^{a}$$

may be determined by using Equation (3.1) and Equation (3.2):

$${b}_{k}^{ω} = {b}_{base} ( {T}_{k} ) + {Δ b}_{k}^{ω} , \qquad ( 3.1 )$$

$${b}_{k}^{a} = {b}_{base} ( {T}_{k} ) + {Δ b}_{k}^{a} . \qquad ( 3.2 )$$

In the Equation (3.1) and Equation (3.2),

$${Δ b}_{k}^{ω}$$

$$and$$

$${Δ b}_{k}^{a}$$

denote time-varying residual errors of the angular velocity and the acceleration at the time k, respectively. The time-varying residual errors are included as part of the state vector. The time-varying residual errors may be estimated by a Kalman filter. At this point, the modeling of the output of the IMU becomes Equation (4.1) and Equation (4.2):

$${ω}_{k}^{imu} = {ω}_{k} + \vert {b}_{base} ( {T}_{k} ) + {Δ b}_{k}^{ω} \vert + {w}_{k}^{ω} , \qquad ( 4.1 )$$

$${a}_{k}^{imu} = {a}_{k} + \vert {b}_{base} ( {T}_{k} ) + {Δ b}_{k}^{a} \vert + {w}_{k}^{a} . \qquad ( 4.2 )$$

During the state propagation (i.e., step S4), estimation of the bias is implemented based on an estimated value Δb_{k|k} of the bias at a previous time and a noise model. The b_{base}(Tₖ) is directly added to an output compensation of the IMU as a known input.

In some embodiments of the present disclosure, a largest deterministic variation component (temperature drift) in the IMU bias is eliminated by introducing the mapping relationship b_{base}(T) related to temperature.

In some embodiments, the state propagation according to Lie group state equations in step S4 is performed using Equations (5.1) to (5.7):

$${\hat{R}}_{k + 1 \vert k}^{N} = {\hat{R}}_{k \vert k}^{N} exp ( {( {ω}_{k} dt )}_{x} ) \qquad ( 5.1 )$$

$${\hat{v}}_{k + 1 \vert k}^{N} = {\hat{v}}_{k \vert k}^{N} + ( {\hat{R}}_{k \vert k}^{N} {a}_{k} + g ) dt \qquad ( 5.2 )$$

$${\hat{p}}_{k + 1 \vert k}^{N} = {\hat{p}}_{k \vert k}^{N} + {\hat{v}}_{k \vert k}^{N} dt \qquad ( 5.3 )$$

$${\hat{b}}_{k + 1 \vert k}^{ω} = {\hat{b}}_{k \vert k}^{ω} + {w}_{k}^{{b}_{ω}} \qquad ( 5.4 )$$

$${\hat{b}}_{k + 1 \vert k}^{a} = {\hat{b}}_{k \vert k}^{a} + {w}_{k}^{{b}_{a}} \qquad ( 5.5 )$$

$${\hat{R}}_{k + 1 \vert k}^{C} = {\hat{R}}_{k \vert k}^{C} exp ( {( {w}_{k}^{{R}^{C}} dt )}_{x} ) \qquad ( 5.6 )$$

$${\hat{p}}_{k + 1 \vert k}^{C} = {\hat{p}}_{k \vert k}^{C} + {w}_{k}^{{p}^{C}} \qquad ( 5.7 )$$

In the above equations, a subscript k+1|k denotes estimating data at a time k+1 by using data at the time k. g denotes a gravitational acceleration.

$${w}_{k}^{{b}_{ω}}$$

denotes a random error of the angular velocity bias at the time k.

$${w}_{k}^{{b}_{a}}$$

denotes a random error of the acceleration bias at the time k.

$${w}_{k}^{{R}^{C}}$$

denotes a random error of the rotation of the lever arm at the time k.

$${w}_{k}^{{p}^{C}}$$

denotes a random error of the displacement of the lever arm at the time k.

In some embodiments, calculating propagation of the covariance matrix in step S5 is performed using Equation (6):

$${P}_{k + 1 \vert k} = {F}_{k} {P}_{k \vert k} {F}_{k}^{T} + {G}_{k} {Q}_{k} {G}_{k}^{T} . \qquad ( 6 )$$

In the Equation (6), Fₖ denotes a Jacobian matrix of the state equation with respect to the Lie-algebra error at the time k. The Gₖ denotes a noise driving matrix at the time k. The P_{k|k} denotes a covariance matrix of the Lie-algebra error at the time k. The Qₖ denotes a noise covariance matrix at the time k.

In some embodiments, in step S6, the left-invariant observation equation

$${y}_{k + 1}^{L}$$

and the right-invariant observation equation

$${y}_{k + 1}^{R}$$

are established using Equations (7.1) to (7.3):

$${y}_{k + 1}^{L} = {p}_{k + 1 \vert k}^{N} + {n}_{k}^{G N S S} , \qquad ( 7.1 )$$

$${v}_{k + 1}^{C} = [ \begin{matrix}{v}_{k + 1}^{for} \\ {v}_{k + 1}^{kat} \\ {v}_{k + 1}^{up}\end{matrix} ] = {( {\hat{R}}_{k + 1 \vert k}^{c} )}^{T} ( {( {\hat{R}}_{k + 1 \vert k}^{N} )}^{T} {\hat{v}}_{k + 1 \vert k}^{N} + {( {ω}_{k} )}_{\times } {\hat{p}}_{k + 1 \vert k}^{c} ) , \qquad ( 7.2 )$$

$${y}_{k + 1}^{R} = [ \begin{matrix}{v}_{k}^{lat} \\ {v}_{k}^{u p}\end{matrix} ] + {n}_{k}^{v} . \qquad ( 7.3 )$$

In the above equations,

$${p}_{k + 1 \vert k}^{N}$$

denotes an estimated position state vector.

$${n}_{k}^{G N S S}$$

denotes a GNSS observation noise at the time k.

$${n}_{k}^{v}$$

denotes an NHC observation noise at the time k.

$${v}_{k + 1}^{C} = [ \begin{matrix}{v}_{k + 1}^{for} \\ {v}_{k + 1}^{lat} \\ {v}_{k + 1}^{up}\end{matrix} ]$$

denotes velocities of the vehicle at the time k+1.

$${v}_{k + 1}^{f o r}$$

denotes a forward velocity at the time k+1.

$${v}_{k + 1}^{lat}$$

denotes a lateral velocity at the time k+1.

$${v}_{k}^{u p}$$

denotes a vertical velocity at the time k.

$${\hat{R}}_{k + 1 \vert k}^{C}$$

denotes an estimated value of a rotation matrix representing a relationship between the lever arm of the IMU and the vehicle centerIMU and the vehicle center.

$${\hat{p}}_{k + 1 \vert k}^{C}$$

denotes an estimated value of a displacement vector of the lever arm.

In some embodiments of the present disclosure, design of the left-invariant observation equation and the right-invariant observation equation is considered. Through the left-invariant observation equation and the right-invariant observation equation, the constraint conditions in vehicle motion are better described, endowing the filtering process with improved invariance to transformations and rotations during motion, thereby reducing the error propagation issues that may exist in traditional EKF manners.

Further, embodiments of the present disclosure also improve overall positioning accuracy via optimization of error modeling and observation update. Information such as the forward velocity, the lateral velocity, and the vertical velocity of the vehicle is introduced into filtering equations. The information provides more precise kinematic information for state estimation, thereby improving accuracy of the state estimation.

In some embodiments, the mapping a left-invariant covariance matrix and a right-invariant covariance matrix via a common state covariance matrix in step S7 is performed using Equations (8.1) to (8.4):

$${P}_{k + 1 \vert k + 1}^{L} = {F}_{k + 1}^{L} {{P}_{S t a t e} ( {F}_{k + 1}^{L} )}^{T} \qquad ( 8.1 )$$

$${P}_{S t a t e} = {( {F}_{k + 1}^{L} )}^{- 1} {{P}_{k + 1 \vert k + 1}^{L} ( {( {F}_{k + 1}^{L} )}^{- 1} )}^{T} \qquad ( 8.2 )$$

$${P}_{k + 1 \vert k + 1}^{R} = {F}_{k + 1}^{R} {{P}_{S t a t e} ( {F}_{k + 1}^{R} )}^{T} \qquad ( 8.3 )$$

$${P}_{S t a t e} = {( {F}_{k + 1}^{R} )}^{- 1} {{P}_{k + 1 \vert k + 1}^{R} ( {( {F}_{k + 1}^{R} )}^{- 1} )}^{T} \qquad ( 8.4 )$$

In the above equations, Pₛₜₐₜₑ denotes the common state covariance matrix.

$${P}_{k + 1 \vert k + 1}^{L}$$

denotes the left-invariant covariance matrix (also referred to as a covariance matrix of a left-invariant Lie-algebra error) at the time k+1.

$${P}_{k + 1 \vert k + 1}^{R}$$

denotes the right-invariant covariance matrix (also referred to as a covariance matrix of a right-invariant Lie-algebra error) at the time k+1.

$${F}_{k + 1}^{L}$$

denotes a Jacobian matrix of a left-invariant state equation with respect to the Lie-algebra error at the time k+1.

$${F}_{k + 1}^{R}$$

denotes a Jacobian matrix of a right-invariant state equation with respect to the Lie-algebra error at the time k+1.

Merely by way of example, a specific embodiment of the method for performing sequential invariant extended Kalman filtering in a navigation and positioning task includes the following steps:

Step 1, dividing observations of navigation sensors into two types according to a frame in which the navigation sensors are located. One type is observations in a body frame of a vehicle, and the other type is observations in a navigation frame, for example, one type includes the NHC. The other type includes navigation information provided in the navigation frame, for example, the other type includes a position provided by the GNSS.

Step 2, constructing a state vector. The state vector is written in the Lie group form:

The state vector to be estimated is:

$${\hat{χ}}_{k} := ( {{R}^{`}}_{k}^{N} , {{v}^{`}}_{k}^{N} , {{p}^{`}}_{k}^{N} , {{b}^{`}}_{k}^{ω} , {{b}^{`}}_{k}^{a} , {{R}^{`}}_{k}^{C} , {{p}^{`}}_{k}^{C} ) .$$

The lie group form of the state vector is shown in Equation (1):

$${\hat{χ}}_{k} = ( \begin{matrix}{\hat{R}}_{k} \\ {\hat{x}}_{k} \\ {\hat{X}}_{k}\end{matrix} ) = ( {\hat{R}}_{k} , {\hat{x}}_{k} , {\hat{x}}_{k} ) . \qquad ( 1 )$$

In Equation (1):

$${\hat{R}}_{k} = ( {\hat{R}}_{k}^{N} , {\hat{R}}_{k}^{C} ) \qquad ( 1.1 )$$

$${\hat{x}}_{k} = ( {\hat{v}}_{k}^{N} , {\hat{p}}_{k}^{N} ) \qquad ( 1.2 )$$

$${\hat{x}}_{k} = ( {\hat{b}}_{k}^{ω} , {\hat{b}}_{k}^{a} , {\hat{p}}_{k}^{C} ) . \qquad ( 1.3 )$$

In the above equations,

$${\hat{R}}_{k}^{N} , {\hat{v}}_{k}^{N} , {\hat{p}}_{k}^{N}$$

denote the attitude estimate, the velocity estimate, and the position estimate of the vehicle in the navigation frame at the time k, respectively.

$${\hat{b}}_{k}^{ω} and {\hat{b}}_{k}^{a}$$

denote the estimated value of gyroscope bias and the estimated value of accelerometer bias of the IMU at the time k, respectively.

$${\hat{R}}_{k}^{C} and {\hat{p}}_{k}^{C}$$

denote the estimated value of rotation and the estimated value of displacement of the lever arm of the IMU relative to the vehicle center at the time k, respectively.

Step 3, performing modeling on an output of the IMU using Equations (2.1) and (2.2):

$${ω}_{k}^{i m u} = {ω}_{k} + {b}_{k}^{ω} + {w}_{k}^{ω} , \qquad ( 2.1 )$$

$${a}_{k}^{i m u} = {a}_{k} + {b}_{k}^{a} + {w}_{k}^{a} . \qquad ( 2.2 )$$

In Equations (2.1) and (2.2), ωₖ and aₖ denote true values of the angular velocity and the acceleration of the IMU at the time k, respectively.

$${ω}_{k}^{i m u} and {a}_{k}^{i m u}$$

denote the output values of the IMU at the time k.

$${b}_{k}^{ω} and {b}_{k}^{a}$$

denote the angular velocity bias and the acceleration bias at the time k, respectively.

$${w}_{k}^{ω} and {w}_{k}^{a}$$

denote random errors of the angular velocity and the acceleration at the time k, respectively.

Step 4, performing state propagation, where propagation equations are shown in Equations (5.1) to (5.7):

$${\hat{R}}_{k + 1 \vert k}^{N} = {\hat{R}}_{k \vert k}^{N} exp ( {( {ω}_{k} d t )}_{\times } ) \qquad ( 5.1 )$$

$${\hat{v}}_{k + 1 \vert k}^{N} = {\hat{v}}_{k \vert k}^{N} + ( {\hat{R}}_{k \vert k}^{N} {a}_{k} + g ) d t \qquad ( 5.2 )$$

$${\hat{p}}_{k + 1 \vert {k}^{=}}^{N} {\hat{p}}_{k \vert k}^{N} + {\hat{v}}_{k \vert k}^{N} d t \qquad ( 5.3 )$$

$${\hat{b}}_{k + 1 \vert k}^{ω} = {\hat{b}}_{k \vert k}^{ω} + {w}_{k}^{{b}_{ω}} \qquad ( 5.4 )$$

$${\hat{b}}_{k + 1 \vert k}^{a} = {\hat{b}}_{k \vert k}^{a} + {w}_{k}^{{b}_{a}} \qquad ( 5.5 )$$

$${\hat{R}}_{k + 1 \vert k}^{C} = {\hat{R}}_{k \vert k}^{C} exp ( {( {ω}_{k}^{{R}^{c}} d t )}_{\times } ) \qquad ( 5.6 )$$

$${\hat{p}}_{k + 1 \vert k}^{C} = {\hat{p}}_{k \vert k}^{C} + {w}_{k}^{{p}^{C}} \qquad ( 5.7 )$$

The subscript k+1|k denotes the estimating data at the time k+1 by using the data at the time k.

Step 5, calculating propagation of a covariance matrix, the error covariance matrix P_{k+1|k} in the propagation process being shown in Equation (6):

$${P}_{k + 1 \vert k} = {F}_{k} {P}_{k \vert k} {F}_{k}^{T} + {G}_{k} {Q}_{k} {G}_{k}^{T} . \qquad ( 6 )$$

In Equation (6), Fₖ denotes the Jacobian matrix of the state equation with respect to the Lie-algebra error at the time k. Gₖ denotes the noise driving matrix.

Step 6, establishing observation equations according to the two types of observations, where the left-invariant observation equation

$${y}_{k + 1}^{L}$$

and the right-invariant observation equation

$${y}_{k + 1}^{R}$$

may be shown in Equations (7.1) to (7.3):

$${y}_{k + 1}^{L} = {p}_{k + 1 \vert k}^{N} + {n}_{k}^{G N S S} , \qquad ( 7.1 )$$

$${v}_{k + 1}^{C} = [ \begin{matrix}{v}_{k + 1}^{for} \\ {v}_{k + 1}^{lat} \\ {v}_{k + 1}^{up}\end{matrix} ] = {( {\hat{R}}_{k + 1 \vert k}^{C} )}^{T} ( {( {\hat{R}}_{k + 1 \vert k}^{N} )}^{T} {\hat{v}}_{k + 1 \vert k}^{N} + {( {ω}_{k} )}_{\times } {\hat{p}}_{k + 1 \vert k}^{C} ) , \qquad ( 7.2 )$$

$${y}_{k + 1}^{R} = [ \begin{matrix}{v}_{k , u}^{lat} \\ {v}_{k}^{up}\end{matrix} ] + {n}_{k}^{v} . \qquad ( 7.3 )$$

In the above equations,

$${n}_{k}^{GNSS}$$

denotes the GNSS observation noise,

$${v}_{k + 1}^{C} = [ \begin{matrix}{v}_{k + 1}^{for} \\ {v}_{k + 1}^{lat} \\ {v}_{k + 1}^{up}\end{matrix} ]$$

denotes the velocities of the vehicle at the time k+1,

$${v}_{k + 1}^{for}$$

denotes the forward velocity at the time k+1,

$${v}_{k + 1}^{lat}$$

denotes the lateral velocity, and

$${v}_{k}^{up}$$

denotes the vertical velocity.

$${\hat{R}}_{k + 1 \vert k}^{{}_{C}}$$

denotes the rotation matrix representing the relationship between the lever arm of the IMU and the vehicle center, and

$${\hat{p}}_{k + 1 \vert k}^{C}$$

denotes the displacement vector of the lever arm.

According to the definition of the invariant extended Kalman filter, equations for left-invariant (zₖ₊₁) and right-invariant (zₖ₊₁) forms may be written as Equation (9.1) and Equation (9.2):

$${z}_{k + 1} = {( {{R}^{`}}_{k + 1 \vert k}^{{}_{N}} )}^{- 1} * ( {y}_{k + 1}^{{}_{L}} - {{p}^{`}}_{k + 1 \vert k} ) \qquad ( 9.1 )$$

$${z}_{k + 1} = {( {{R}^{`}}_{k + 1 \vert k}^{{}_{C}} )}^{T} ( {( {{R}^{`}}_{k + 1 \vert k}^{{}_{N}} )}^{{T}_{}} {{v}^{`}}_{k + 1 \vert k}^{{}_{N}} + {( {ω}_{k} )}_{\times } {{p}^{`}}_{k + 1 \vert k}^{{}_{C}} ) \qquad ( 9.2 )$$

Step 7, updating the state estimation using Equation (10):

$$\{ \begin{matrix}{\hat{χ}}_{k + 1 \vert k + 1} = {\hat{χ}}_{k + 1 \vert k} \cdot {L}_{k + 1} ( {z}_{k + 1} ) & [ Updatestep : LlEKF ] \\ {\hat{χ}}_{k + 1 \vert k + 1} = {L}_{k + 1} ( {z}_{k + 1} ) \cdot {\hat{χ}}_{k + 1 \vert k} & [ Updatestep : RIEKF ]\end{matrix} \qquad ( 10 )$$

In Equation (10), \hat{χ}_{k+1|k+1} denotes a Lie group estimate of a system state (e.g., the attitude estimate, the velocity estimate, and the position estimate of the vehicle) at the time k+1, Lₖ(z) is as shown in Equation (11.1) and Equation (11.2), and Lₖ(z) denotes a Lie-group correction term obtained by applying an exponential map to Kz:

$${L}_{k} ( z ) = ( {L}_{k}^{R} ( z ) , {L}_{k}^{x} ( z ) , {L}_{k}^{x} ( z ) ) ∈ SO ( 3 ) \times {ℝ}^{3} \times {ℝ}^{3} \qquad ( 11.1 )$$

$${L}_{k} ( z ) = {exp}_{{G}_{V , B}^{+}} ( Kz ) \qquad ( 11.2 )$$

In the above equations, K denotes a Kalman filter gain,

$${exp}_{{G}_{V , B}^{+}}$$

denotes the exponential map, a specific calculation process of the exponential map is given by Equation (12), ξ^{R} denotes a Lie-algebra error associated with rotation

$${ξ}_{1}^{x}$$

denotes a Lie-algebra error in a vector form, and

$${ξ}_{2}^{x}$$

denotes a Lie algebra error in a scalar form:

$${exp}_{{G}_{{N}_{1} , {N}_{2}}^{+}} ( \begin{matrix}{ξ}^{R} \\ {ξ}_{1}^{x} \\ ⋮ \\ {ξ}_{{N}_{1}}^{x} \\ {ξ}_{1}^{x} \\ ⋮ \\ {ξ}_{{N}_{2}}^{x}\end{matrix} ) = ( \begin{matrix}{exp}_{SO ( d )} ( {ξ}^{R} ) \\ {v}_{d} ( {ξ}^{R} ) {ξ}_{1}^{x} \\ ⋮ \\ {v}_{d} ( {ξ}^{R} ) {ξ}_{{N}_{1}}^{x} \\ {v}_{d} ( - {ξ}^{R} ) {ξ}_{1}^{x} \\ ⋮ \\ {v}_{d} ( - {ξ}^{R} ) {ξ}_{{N}_{2}}^{x}\end{matrix} ) \\ {v}_{3} ( ξ ) = {I}_{3} + \frac{1 - cos ( ‖ ξ ‖ )}{{‖ ξ ‖}^{2}} {( ξ )}_{\times } + \frac{‖ ξ ‖ - sin ( ‖ ξ ‖ )}{{‖ ξ ‖}^{3}} {( ξ )}_{\times }^{2} \\ {v}_{2} ( ξ ) = \frac{sin ‖ ξ ‖}{‖ ξ ‖} I + \frac{1 - cos ‖ ξ ‖}{‖ ξ ‖} J \\ J : = ρ ( π / 2 ) \qquad ( 12 )$$

The subscript d denotes dimension, and ρ(θ) denotes a 2*2 rotation matrix of an angle θ. Expand \hat{χ}_{k+1|k+1} to Equation (13.1) and Equation (13.2):

$${\hat{χ}}_{k + 1 \vert k + 1} = ( \begin{matrix}{R}_{k + 1 \vert k} {L}_{k + 1}^{R} ( {z}_{k + 1} ) \\ {\hat{x}}_{k + 1 \vert k} + {R}_{k + 1 \vert k}^{N} * {L}_{k + 1}^{x} ( {z}_{k + 1} ) \\ {L}_{k + 1}^{x} ( {z}_{k + 1} ) + {{L}_{k + 1}^{R} ( {z}_{k + 1} )}^{- 1} * {\hat{x}}_{k + 1 \vert k}\end{matrix} ) [ L ] \qquad ( 13.1 )$$

$${\hat{χ}}_{k + 1 \vert k + 1} = ( \begin{matrix}{L}_{k + 1}^{R} ( {z}_{k + 1} ) {\hat{R}}_{k + 1 \vert k} \\ {L}_{k + 1}^{x} ( {z}_{k + 1} ) + {L}_{k + 1}^{R} ( {z}_{k + 1} ) * {\hat{x}}_{k + 1 \vert k} \\ {\hat{x}}_{k + 1 \vert k} + {( {\hat{R}}_{k + 1 \vert k}^{{}_{N}} )}^{- 1} * {L}_{k + 1}^{x} ( {z}_{k + 1} )\end{matrix} ) [ R ] \qquad ( 13.2 )$$

$$where :$$

$$S = ( {H}_{k + 1} {P}_{k + 1 \vert k} {H}_{k + 1}^{T} + {N}_{k + 1} ) , \qquad ( 14.1 )$$

$$K = {P}_{k + 1 \vert k} {H}_{k + 1}^{T} / S , \qquad ( 14.2 )$$

$${P}_{k + 1 \vert k} = ( I - {KH}_{k + 1} ) {P}_{k + 1 \vert k} \qquad ( 14.3 )$$

$${P}_{k + 1 \vert k}^{L} = {F}_{k}^{L} {{P}_{k \vert k}^{L} ( {F}_{k}^{L} )}^{T} + {G}_{k}^{L} {{Q}_{k}^{L} ( {G}_{k}^{L} )}^{T} \qquad ( 14.4 )$$

$${P}_{k + 1 \vert k}^{R} = {F}_{k}^{R} {{P}_{k \vert k}^{R} ( {F}_{k}^{R} )}^{T} + {G}_{k}^{R} {{Q}_{k}^{R} ( {G}_{k}^{R} )}^{T} \qquad ( 14.5 )$$

In the above equations,

$${F}_{k}^{L}$$

denotes a Jacobian matrix of the left-invariant state equation with respect to the left-invariant Lie-algebra error at the time k, and

$${F}_{k}^{R}$$

denotes a Jacobian matrix of the right-invariant state equation with respect to the right-invariant Lie-algebra error at the time k.

$${G}_{k}^{L}$$

denotes a noise driving matrix of the left-invariant Lie-algebra error with respect to a process noise at the time k,

$${G}_{k}^{R}$$

denotes a noise driving matrix of the right-invariant Lie-algebra error with respect to the process noise at the time k. Hₖ₊₁ denotes a constructed observation matrix at the time k+1, and Nₖ₊₁ denotes an observation error matrix at the time k+1.

The propagation law of the process state noise in the update step is modeled by Equations (15.1) to (15.6):

$${P}_{k + 1 \vert k + 1}^{L} = ( I - {K}^{L} {H}_{k + 1}^{L} ) {P}_{k + 1 \vert k}^{L} \qquad ( 15.1 )$$

$${P}_{k + 1 \vert k + 1}^{R} = ( I - {K}^{R} {H}_{k + 1}^{R} ) {P}_{k + 1 \vert k}^{R} \qquad ( 15.2 )$$

$${S}^{L} = ( {H}_{k + 1}^{L} {{P}_{k + 1 \vert k}^{L} ( {H}_{k + 1}^{L} )}^{T} + {N}_{k + 1}^{L} ) \qquad ( 15.3 )$$

$${K}^{L} = {{P}_{k + 1 \vert k}^{L} ( {H}_{k + 1}^{L} )}^{T} / {S}^{L} , \qquad ( 15.4 )$$

$${S}^{R} = ( {H}_{k + 1}^{R} {{P}_{k + 1 \vert k}^{R} ( {H}_{k + 1}^{R} )}^{T} + {N}_{k + 1}^{R} ) , \qquad ( 15.5 )$$

$${K}^{R} = {{P}_{k + 1 \vert k}^{R} ( {H}_{k + 1}^{R} )}^{T} / {S}^{R} , \qquad ( 15.6 )$$

Using the common state covariance matrix Pₛₜₐₜₑ, the left-invariant covariance matrix

$${P}_{k + 1 \vert k + 1}^{L}$$

of the left-invariant Lie-algebra error and the right-invariant covariance matrix

$${P}_{k + 1 \vert k + 1}^{R}$$

of the right-invariant Lie-algebra error are transformed. Finally, the iterative process is completed as shown in Equations (8.1) to (8.4):

$${P}_{k + 1 \vert k + 1}^{L} = {F}_{k + 1}^{L} {{P}_{S t a t e} ( {F}_{k + 1}^{L} )}^{T} \qquad ( 8.1 )$$

$${P}_{S t a t e} = {( {F}_{k + 1}^{L} )}^{- 1} {{P}_{k + 1 \vert k + 1}^{L} ( {( {F}_{k + 1}^{L} )}^{- 1} )}^{T} \qquad ( 8.2 )$$

$${P}_{k + 1 \vert k + 1}^{R} = {F}_{k + 1}^{R} {{P}_{S t a t e} ( {F}_{k + 1}^{R} )}^{T} \qquad ( 8.3 )$$

$${P}_{S t a t e} = {( {F}_{k + 1}^{R} )}^{- 1} {{P}_{k + 1 \vert k + 1}^{R} ( {( {F}_{k + 1}^{R} )}^{- 1} )}^{T} \qquad ( 8.4 )$$

To verify the effectiveness of the embodiments of the present disclosure, a 5 km test was conducted on complex urban roads. In the test, the average positioning accuracy achieved by the method of the present disclosure reached 1.1 m. Compared with single GNSS positioning (4.2 m) and a conventional EKF-based fusion method (2.5 m), the positioning accuracy was improved by 73.8% and 56%, respectively (as shown in Table 1). In dynamic scenarios (such as sharp turns and acceleration/braking), the attitude estimation error was reduced by more than 40%, effectively suppressing drift caused by accumulated IMU bias.

TABLE 1

| | Average Positioning |
|---|---|
| Method | Accuracy (m) |
| GNSS | 4.2 m |
| EKF-based GNSS/IMU integrated | 2.5 m |
| positioning | |
| Method proposed in the present disclosure | 1.1 m |

Through sequential and synchronous update of a left-invariant IEKF (L-IEKF) and a right-invariant IEKF (R-IEKF), the method solves the problem that a conventional IEKF cannot simultaneously fuse observations in a navigation frame (such as GNSS positions) and observations in a body frame (such as a zero-velocity assumption and wheel speed). For example, GNSS position information can be directly used to correct a global pose, thereby avoiding nonlinear interference of vehicle motion with the observation model. In addition, the offset between the IMU and the vehicle center is dynamically compensated by a lever-arm parameter, thereby improving the modeling accuracy of lateral and vertical velocity constraints.

A common state covariance matrix is introduced to realize mutual mapping between the covariance of the left-invariant error and the covariance of the right-invariant error. Specifically, the covariance matrices of the left and right IEKFs are uniformly transformed into a common state space through a Jacobian matrix, thereby avoiding covariance distortion caused by coordinate system differences. Geometric invariance of error propagation is maintained during the update process, reducing linearization approximation errors and improving filtering stability by approximately 30%.

In urban canyon areas where GNSS signals are weak and multipath effects are severe, the method fuses high-frequency IMU data with sparse GNSS observations, thereby reducing positioning outage duration to less than 20% of that of conventional methods.

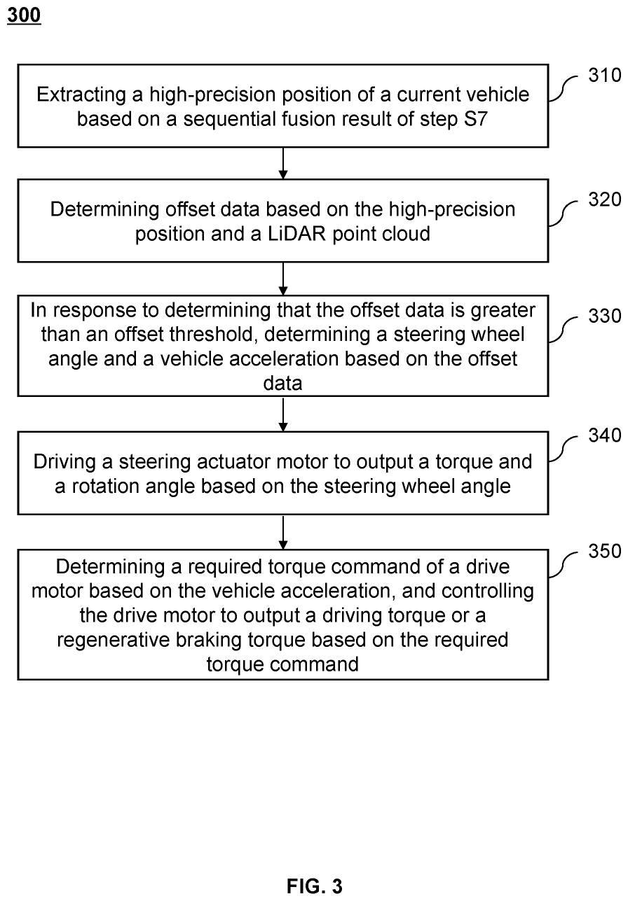

FIG. 3 is a flowchart of another exemplary process for sequential invariant extended Kalman filtering in a navigation and positioning task according to some embodiments of the present disclosure. As shown in FIG. 3, a process 300 includes the following steps 310 to 350. In some embodiments, the process 300 may be executed by the control system.

In some embodiments, when a vehicle (e.g., an electric vehicle or a hybrid vehicle) may be driven by a motor, the method for performing sequential invariant extended Kalman filtering in a navigation and positioning task further includes: extracting a high-precision position of a current vehicle based on a sequential fusion result of step S7; determining offset data based on the high-precision position and a LiDAR point cloud; in response to determining that the offset data is greater than an offset threshold, determining a steering wheel angle and a vehicle acceleration based on the offset data; driving a steering actuator motor to output a torque and a rotation angle based on the steering wheel angle; and determining a required torque command of a drive motor based on the vehicle acceleration, and controlling the drive motor to output a driving torque or a regenerative braking torque based on the required torque command.

The drive motor refers to a motor that drives the vehicle to move. The steering actuator motor refers to a motor that drives the vehicle to steer.

Step 310, extracting a high-precision position of the current vehicle based on the sequential fusion result of step S7.

The sequential fusion result refers to an optimal state estimation that is output in step S7 by performing mapping via the common state covariance matrix, i.e., \hat{χ}_{k+1|k+1}. For example, the sequential fusion result may include optimal estimates for various state quantities such as attitude, velocity, position, bias, and lever arm parameters.

The high-precision position of the current vehicle refers to coordinates that accurately reflect a position of the current vehicle in the navigation frame. For example, the control system may read a position component

$${{p}^{‵}}_{k + 1 \vert k + 1}^{{}_{N}}$$

from the sequential fusion result \hat{χ}_{k+1|k+1} as the high-precision position of the current vehicle.

Step 320, determining offset data based on the high-precision position and a LiDAR point cloud.

The LiDAR point cloud refers to a set of three-dimensional spatial point coordinates of an environment surrounding the vehicle, which is acquired by a LIDAR sensor via transmitting and receiving laser beams. The LiDAR sensor may be a vehicle-mounted LiDAR installed on the vehicle. In some embodiments, the control system may obtain a set of coordinates scanned by the LiDAR sensor in real time as the LiDAR point cloud.

The offset data refers to data reflecting a deviation between an actual pose of the current vehicle and a desired pose. For example, the offset data may include a lateral position error, a heading error, etc.

In some embodiments, the control system may determine the offset data in a plurality of ways based on the high-precision position and the LiDAR point cloud. For example, the control system may match the LiDAR point cloud with a high-definition map. After the matching is completed, the control system may query a desired position and a desired heading corresponding to the high-precision position of the current vehicle based on a vehicle task (e.g., lane keeping or path tracking) and global path planning. The control system may calculate the lateral position error and the heading error based on the high-precision position and the corresponding desired position and desired heading, and use the lateral position error and the heading error as the offset data. The high-definition map refers to a digital map designed specifically for an autonomous driving system with centimeter-level precision, which may be pre-stored in the control system. Before matching with the LiDAR point cloud, the high-definition map requires frame conversion according to the frame in which the high-precision position is located.

Step 330, in response to determining that the offset data is greater than an offset threshold, determining a steering wheel angle and a vehicle acceleration based on the offset data.

The offset threshold refers to a preset critical value used for determining whether a vehicle deviation requires active correction. For example, the offset threshold may include a lateral offset threshold and a heading offset threshold.

In some embodiments, when the lateral position error in the offset data is greater than the lateral offset threshold and/or the heading error is greater than the heading offset threshold, the offset data is determined to be greater than the offset threshold.

In some embodiments, the offset threshold is related to a controllability. The controllability is related to a current covariance matrix and a visibility.

The controllability refers to a quantitative scalar metric used to measure the ability and difficulty for the control system to stably and accurately control the vehicle to return to an expected trajectory under a current state and at a current moment. In some embodiments, the offset threshold may be positively correlated with the controllability. For example, when the controllability is high, it indicates that the control system is likely to quickly correct a relatively large deviation, and a larger offset threshold may be used. When the controllability is low, the control system should initiate a correction action earlier and more cautiously, and a smaller offset threshold may be used.

The current covariance matrix refers to a covariance matrix of a Lie-algebra error acquired after propagation in step S5 and update in step S7, i.e., P_{k+1|k+1}.

The visibility refers to an indicator reflecting availability of effective environmental features used for positioning. The higher the visibility is, the more reliable the positioning observations are. In some embodiments, the visibility is positively correlated with a count of feature points in the LiDAR point cloud that are successfully matched with the high-definition map, an effective density of the point cloud, a uniformity of distribution of features within a field of view, or the like.

In some embodiments, the control system may determine the controllability in a plurality of ways based on the current covariance matrix and the visibility. For example, the control system may extract an uncertainty indicator from the current covariance matrix, such as calculating a covariance of a position estimation component to obtain a position uncertainty. When the position uncertainty is larger or the visibility is lower, the controllability is lower.

In some embodiments of the present disclosure, “conditional control” is achieved by dynamically coupling control decision-making with upstream positioning confidence, i.e., the covariance, and environmental perception quality, i.e., the visibility. When system uncertainty is high, a more conservative strategy is automatically adopted, fundamentally avoiding safety risks that may be caused by “blind control.” By correlating the setting of the offset threshold with the controllability, an autonomous driving system can better cope with complex scenarios such as GNSS signal loss and adverse weather. For example, in a tunnel where the visibility may be normal but the positioning covariance increases due to the absence of GNSS, the system automatically relaxes the control threshold and relies on more conservative dead reckoning or prompts a takeover, thereby improving robustness of the system.

The steering wheel angle refers to an angle by which front wheels need to turn in order for the vehicle to return to a desired path.

In some embodiments, the control system may determine the steering wheel angle in a plurality of ways based on the offset data. For example, the control system may calculate the steering wheel angle based on the offset data (e.g., the lateral position error and the heading error) and a current vehicle speed through preview tracking control (e.g., a pure pursuit algorithm or a Stanley algorithm) or model predictive control.

The vehicle acceleration refers to a longitudinal acceleration required to return the vehicle to a desired path or maintain a safe distance. The vehicle acceleration may be positive or negative. A positive value indicates acceleration, and a negative value indicates braking or deceleration.

In some embodiments, the control system may determine the vehicle acceleration in a plurality of ways based on the offset data. For example, the control system may determine the vehicle acceleration by querying a first preset table based on the offset data and a current speed. The first preset table includes a correspondence relationship among the offset data, the current speed, and the vehicle acceleration, which may be preset according to prior knowledge or historical experience.

Step 340, driving a steering actuator motor to output a torque and a rotation angle based on the steering wheel angle.

In some embodiments, the control system may drive the steering actuator motor to output the torque and the rotation angle based on the steering wheel angle to achieve control of a wheel steering angle of the vehicle.

Step 350, determining a required torque command of a drive motor based on the vehicle acceleration, and controlling the drive motor to output a driving torque or a regenerative braking torque based on the required torque command.

The required torque command refers to a command for controlling a torque to be output by the drive motor (or absorbed by a regenerative braking system) in order to achieve the vehicle acceleration. For example, the required torque command may include a torque value to be output by the drive motor (or absorbed by the regenerative braking system).

In some embodiments, the control system may determine the required torque command of the drive motor in a plurality of ways based on the vehicle acceleration. For example, the control system may determine the required torque command for the drive motor based on the vehicle acceleration by querying a second preset table. The second preset table includes a correspondence relationship between the vehicle acceleration and the required torque command for the drive motor, which may be preset according to prior knowledge or historical experience.

In some embodiments, the control system may control the drive motor to output the driving torque or the regenerative braking torque according to the required torque command to achieve control of the vehicle acceleration of the vehicle.

In some embodiments of the present disclosure, by controlling the motor according to the above method, since the control of the wheel steering angle and the vehicle acceleration of the vehicle is based on high-precision and geometrically consistent positioning results, the accuracy of path tracking and speed control can be fundamentally ensured, thereby reducing control oscillation or deviation caused by positioning errors.

Some embodiments of the present disclosure further provide a computer device. The computer device includes a memory and a processor. Computer instructions are stored in the memory. When the processor runs the computer instructions stored in the memory, the processor executes the method for performing sequential invariant extended Kalman filtering in a navigation and positioning task described in the present disclosure.

Some embodiments of the present disclosure further provide a non-transitory computer-readable storage medium storing computer instructions. When the computer instructions are executed by a processor, the method for performing sequential invariant extended Kalman filtering in a navigation and positioning task described in the present disclosure is performed.

Those skilled in the art may understand that the embodiments of the present disclosure may be provided as a method, a system, or a computer program product. Accordingly, the present disclosure may take the form of an entirely hardware embodiment, an entirely software embodiment, or an embodiment combining software and hardware aspects. Furthermore, the present disclosure may take the form of a computer program product implemented on one or more computer-usable storage media having computer-usable program code embodied therein, including but not limited to magnetic storage devices, CD-ROMs, optical storage devices, or the like.

The present disclosure has been described with reference to flowcharts and/or block diagrams of methods, apparatuses (systems), and computer program products according to embodiments of the present disclosure. It should be understood that each process and/or block in the flowcharts and/or block diagrams, and combinations of processes and/or blocks in the flowcharts and/or block diagrams, may be implemented by computer program instructions. These computer program instructions may be provided to a processor of a general-purpose computer, a special-purpose computer, an embedded processor, or other programmable data processing apparatus to produce a machine, such that the instructions executed via the processor of the computer or other programmable data processing apparatus create means for implementing the functions specified in one or more processes of the flowcharts and/or one or more blocks of the block diagrams. These computer program instructions may also be stored in a computer-readable memory that can direct a computer or other programmable data processing apparatus to function in a particular manner, such that the instructions stored in the computer-readable memory produce an article of manufacture including instruction means for implementing the functions specified in one or more processes of the flowcharts and/or one or more blocks of the block diagrams.

These computer program instructions may also be loaded onto a computer or other programmable data processing apparatus to cause a series of operational steps to be performed on the computer or other programmable apparatus so as to produce a computer-implemented process, such that the instructions executed on the computer or other programmable apparatus provide steps for implementing the functions specified in one or more processes of the flowcharts and/or one or more blocks of the block diagrams.

Finally, it should be noted that the foregoing embodiments are provided only for illustrating the technical solutions of the present disclosure and are not intended to limit the scope of protection thereof. Although the present disclosure has been described in detail with reference to the foregoing embodiments, those of ordinary skill in the art should understand that various changes, modifications, or equivalent substitutions may be made to the specific embodiments after reading the present disclosure, and such changes, modifications, or equivalent substitutions shall fall within the scope of the pending claims.

What is claimed is:

1. A method for performing sequential invariant extended Kalman filtering in a navigation and positioning task, comprising:
step S1: dividing observations of navigation sensors into two types according to a frame in which the navigation sensors are located, wherein one type is observations in a body frame of a vehicle, and the other type is observations in a navigation frame;
step S2: constructing a state vector in a Lie group form;
step S3: performing modeling on an output of an inertial measurement unit (IMU);
step S4: performing state propagation according to Lie group state equations;
step S5: calculating propagation of a covariance matrix;
step S6: establishing a left-invariant observation equation and a right-invariant observation equation according to the two types of observations divided in the step S1; and
step S7: synchronously updating a state estimation through a left-invariant extended Kalman filter and a right-invariant extended Kalman filter, and mapping a left-invariant covariance matrix and a right-invariant covariance matrix via a common state covariance matrix to complete sequential fusion.

2. The method of claim 1, wherein the observations in the body frame in the step S1 include a Non-Holonomic Constraint (NHC), and the observations in the navigation frame in the step S1 include a position provided by a Global Navigation Satellite System (GNSS).

3. The method of claim 1, wherein the state vector in the Lie group form in the step S2 is:
$$\hat{χ} = ( \begin{matrix}{\hat{R}}_{k} \\ {\hat{x}}_{k} \\ {\hat{X}}_{k}\end{matrix} ) = ( {\hat{R}}_{k} , {\hat{x}}_{k} , {\hat{X}}_{k} ) ,$$
wherein
$${\hat{R}}_{k} = ( {\hat{R}}_{k}^{{}_{N}} , {\hat{R}}_{k}^{{}_{C}} ) , {\hat{x}}_{k} = ( {\hat{v}}_{k}^{N} , {\hat{p}}_{k}^{N} ) , {\hat{X}}_{k} = ( {\hat{b}}_{k}^{{}_{ω}} , {\hat{b}}_{k}^{{}_{a}} , {\hat{p}}_{k}^{{}_{C}} ) ,$$
$${\hat{R}}_{k}^{{}_{N}}$$
denotes an attitude estimate of the vehicle in the navigation frame at a time k,
$${\hat{v}}_{k}^{N}$$
denotes a velocity estimate of the vehicle in the navigation frame at the time k,
$${\hat{p}}_{k}^{{}_{N}}$$
denotes a position estimate of the vehicle in the navigation frame at the time k,
$${\hat{b}}_{k}^{{}_{ω}}$$
denotes an estimated value of gyroscope bias of the IMU at the time k,
$${\hat{b}}_{k}^{a}$$
denotes an estimated value of accelerometer bias at the time k,
$${\hat{R}}_{k}^{C}$$
denotes an estimated value of a rotation of a lever arm of the IMU relative to a vehicle center at the time k, and
$${\hat{p}}_{k}^{C}$$
denotes an estimated value of a displacement of the lever arm of the IMU relative to the vehicle center at the time k.

4. The method of claim 1, wherein the performing modeling on an output of an inertial measurement unit (IMU) in the step S3 includes:
$${ω}_{k}^{imu} = {ω}_{k} + {b}_{k}^{ω} + {w}_{k}^{ω} ,$$
$${a}_{k}^{imu} = {a}_{k} + {b}_{k}^{a} + {w}_{k}^{a} ,$$
wherein ωₖ denotes a true value of an angular velocity of the IMU at the time k, aₖ denotes a true value of an acceleration of the IMU at the time k,
$${ω}_{k}^{imu} and {a}_{k}^{imu}$$
denote output values of the angular velocity and the acceleration of the IMU at the time k,
$${b}_{k}^{ω}$$
denotes an angular velocity bias at the time k,
$${b}_{k}^{a}$$
denotes an acceleration bias at the time k,
$${w}_{k}^{ω}$$
denotes a random error of the angular velocity at the time k, and
$${w}_{k}^{a}$$
denotes a random error of the acceleration at the time k.

5. The method of claim 1, wherein the performing state propagation according to Lie group state equations in the step S4 includes:
$${\hat{R}}_{k + 1 \vert k}^{N} = {\hat{R}}_{k \vert k}^{N} exp ( {( {ω}_{k} dt )}_{\times } )$$
$${\hat{v}}_{k + 1 \vert k}^{N} = {\hat{v}}_{k \vert k}^{N} + ( {\hat{R}}_{k \vert k}^{N} {a}_{k} + g ) dt$$
$${\hat{p}}_{k + 1 \vert k}^{N} = {\hat{p}}_{k \vert k}^{N} + {\hat{v}}_{k \vert k}^{N} dt$$
$${\hat{b}}_{k + 1 \vert k}^{ω} = {\hat{b}}_{k \vert k}^{ω} + {w}_{k}^{{b}_{ω}}$$
$${\hat{b}}_{k + 1 \vert k}^{a} = {\hat{b}}_{k \vert k}^{a} + {w}_{k}^{{b}_{a}}$$
$${\hat{R}}_{k + 1 \vert k}^{C} = {\hat{R}}_{k \vert k}^{C} exp ( {( {w}_{k}^{{R}^{C}} dt )}_{\times } )$$
$${\hat{p}}_{k + 1 \vert k}^{C} = {\hat{p}}_{k \vert k}^{C} + {w}_{k}^{{p}^{C}}$$
wherein a subscript k+1|k denotes estimating data at a time k+1 by using data at the time k, g denotes a gravitational acceleration,
$${w}_{k}^{{b}_{ω}}$$
denotes a random error of angular velocity bias at the time k,
$${w}_{k}^{{b}_{a}}$$
denotes a random error of acceleration bias at the time k,
$${w}_{k}^{{R}^{C}}$$
denotes a random error of the rotation of the lever arm at the time k, and
$${w}_{k}^{{p}^{C}}$$
denotes a random error of the displacement of the lever arm at the time k.

6. The method of claim 5, wherein the calculating propagation of a covariance matrix in the step S5 includes:
$${P}_{k + 1 \vert k} = {F}_{k} {P}_{k \vert k} {F}_{k}^{T} + {G}_{k} {Q}_{k} {G}_{k}^{T}$$
wherein Fₖ denotes a Jacobian matrix of the state equation with respect to a Lie-algebra error at the time k, Gₖ denotes a noise driving matrix at the time k, P_{k|k} denotes a covariance matrix of the Lie-algebra error at the time k, and Qₖ denotes a noise covariance matrix at the time k.

7. The method of claim 6, wherein the establishing a left-invariant observation equation and a right-invariant observation equation in step S6 includes:
$${y}_{k + 1}^{L} = {p}_{k + 1 \vert k}^{N} + {n}_{k}^{G N S S} ,$$
$${v}_{k + 1}^{C} = [ \begin{matrix}{v}_{k + 1}^{o r} \\ {v}_{k + 1}^{1 a t} \\ {v}^{u p}\end{matrix} ] = {( {\hat{R}}_{k + 1 \vert k}^{C} )}^{T} ( {( {\hat{R}}_{k + 1 \vert k}^{N} )}^{T} {\hat{v}}_{k + 1 \vert k}^{N} + {( {ω}_{k} )}_{\times } {\hat{p}}_{k + 1 \vert k}^{c} ) ,$$
$${y}_{k + 1}^{R} = [ \begin{matrix}{v}_{k}^{lat} \\ {v}_{k}^{u p}\end{matrix} ] + {n}_{k}^{v} ,$$
wherein
$${n}_{k}^{G N S S}$$
denotes a GNSS observation noise at the time k,
$${n}_{k}^{v}$$
denotes an NHC observation noise at the time k,
$${v}_{k + 1}^{C} = [ \begin{matrix}{v}_{k + 1}^{for} \\ {v}_{k + 1}^{lat} \\ {v}_{k + 1}^{up}\end{matrix} ]$$
denotes velocities of the vehicle at the time k+1,
$${v}_{k + 1}^{for}$$
denotes a forward velocity at the time k+1,
$${v}_{k + 1}^{lat}$$
denotes a lateral velocity at the time k+1,
$${v}_{k}^{up}$$
denotes a vertical velocity at the time k,
$${\hat{R}}_{k + 1 \vert k}^{C}$$
denotes a rotation matrix representing a relationship between the lever arm of the IMU and the vehicle center, and
$${\hat{p}}_{k + 1 \vert k}^{C}$$
denotes a displacement vector of the lever arm.

8. The method of claim 1, wherein the mapping a left-invariant covariance matrix and a right-invariant covariance matrix via a common state covariance matrix in the step S7 includes:
$${P}_{k + 1 \vert k + 1}^{L} = {F}_{k + 1}^{L} {{P}_{S t a t e} ( {F}_{k + 1}^{L} )}^{T}$$
$${P}_{State} = {( {F}_{k + 1}^{L} )}^{- 1} {{P}_{k + 1 \vert k + 1}^{L} ( {( {F}_{k + 1}^{L} )}^{- 1} )}^{T}$$
$${P}_{k + 1 \vert k + 1}^{R} = {F}_{k + 1}^{R} {{P}_{S t a t e} ( {F}_{k + 1}^{R} )}^{T}$$
$${P}_{State} = {( {F}_{k + 1}^{R} )}^{- 1} {{P}_{k + 1 \vert k + 1}^{R} ( {( {F}_{k + 1}^{R} )}^{- 1} )}^{T}$$
wherein Pₛₜₐₜₑ denotes the common state covariance matrix,
$${P}_{k + 1 \vert k + 1}^{L}$$
denotes a covariance matrix of a left-invariant Lie-algebra error at the time k+1,
$${P}_{k + 1 \vert k + 1}^{R}$$
denotes a covariance matrix of a right-invariant Lie-algebra error at the time k+1,
$${F}_{k + 1}^{L}$$
denotes a Jacobian matrix of a left-invariant state equation with respect to the left-invariant Lie-algebra error at the time k+1, and
$${F}_{k + 1}^{R}$$
denotes a Jacobian matrix of a right-invariant state equation with respect to the right-invariant Lie-algebra error at the time k+1.

9. The method of claim 1, further comprising:
extracting a high-precision position of a current vehicle based on a sequential fusion result of the step S7;
determining offset data based on the high-precision position and a LiDAR point cloud;
in response to determining that the offset data is greater than an offset threshold, determining a steering wheel angle and a vehicle acceleration based on the offset data;
driving a steering actuator motor to output a torque and a rotation angle based on the steering wheel angle; and
determining a required torque command of a drive motor based on the vehicle acceleration, and controlling the drive motor to output a driving torque or a regenerative braking torque based on the required torque command.

10. The method of claim 9, wherein the offset threshold is related to a controllability, and the controllability is related to a current covariance matrix and a visibility.

11. The method of claim 4, wherein the step S3 further includes:
acquiring a mapping relationship b_{base}(T); and
based on a core temperature Tₖ of the IMU at the time k and the mapping relationship b_{base}(T), determining the angular velocity bias
$${b}_{k}^{ω}$$
at the time k and the acceleration bias
$${b}_{k}^{a}$$
at the time k.

12. A computer device, comprising: a memory and a processor, wherein the memory stores computer instructions, and when the processor runs the computer instructions stored in the memory, the processor executes the method for performing sequential invariant extended Kalman filtering in the navigation and positioning task according to claim 1.

13. A non-transitory computer-readable storage medium storing computer instructions, wherein the computer instructions, when executed by a processor, cause the processor to perform the method for performing sequential invariant extended Kalman filtering in the navigation and positioning task according to claim 1.
